(19) United States
(12) Patent Application Publication
(10) Pub. No.: US 2006/0033548 A1
(43) Pub. Date: Feb. 16, 2006

(54) Circuit for translating voltage signal levels

(75) Inventor: Ming-Chih Hsieh, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/044,603

(22) Filed: Jan. 27, 2005

(30) Foreign Application Priority Data
Aug. 13, 2004 (CN) 200410051156.9

(51) Int. Cl. H03L 5/00

(52) U.S. Cl. 327/333

(57) ABSTRACT

A circuit (3) for translating first voltage signal levels to second voltage signal levels includes: a first diode (D1), the anode of the first diode being for receiving the first voltage signal levels; a resistor (R1), one end of the resistor being connected to the cathode of the first diode; and a zener diode (D2), the cathode of the zener diode being connected to the other end of the resistor, and the anode of the zener diode being grounded. The circuit performs voltage signal level translation form the first voltage signal levels to the second voltage signal levels by utilizing the zener break down effect of the zener diode. That is, by switching on and off the zener diode between devices utilizing different logic signal families. The circuit permits communication among such devices without the need for a separate level translation IC.

### CROSS-REFERENCE TO RELATED APPLICATIONS

This application is related to a U.S. patent application entitled “CIRCUIT FOR TRANSLATING VOLTAGE SIGNAL LEVELS”, filed on Dec. 23, 2004 with the same assignee as the instant application and with the Attorney Docket No. 14963-47540. The disclosure of the above identified application is incorporated herein by reference.

### BACKGROUND OF THE INVENTION

1. Field of the Invention

The present invention relates to a electronic circuit for translating RS232 (recommended standard 232) voltage signal levels to Transistor-Transistor-Logic (TTL) voltage signal levels.

2. Description of Related Art

With the rapid development of communication technologies, the Electronic Industries Alliance (EIA) and the Telecommunications Industry Association (TIA) have developed a series of standards to simplify data communication. The RS232 standard is well known in the art, which can recognize voltage signal levels ranging from −12V to +12V. However, other voltage signal levels that are different from the voltage signal levels of the RS232 are also widely used in the electronics and telecommunication industries. In typical devices, most logic signal families utilize narrower and single-direction voltage signal levels. One of such logic signal families is the TTL signal family, which recognizes voltage signal levels ranging from 0V to +5V.

Because the voltage ranges of the RS232 voltage signals is different from that of the TTL voltage signals, devices supporting the RS232 standard (“RS232 devices”) can not communicate with devices utilizing the TTL voltage signals (“TTL devices”) directly.

Generally, devices for translating voltage signal levels are level translation ICs (Integrated Circuits). Level translation ICs can accomplish communication between the RS232 devices and the TTL devices. When TTL voltage signal levels are sent from a TTL device to a level translation IC, the level translation IC translates the TTL voltage signal levels to the signal levels that can be recognized by an RS232 device. Then, the translated voltage signal levels are sent to the RS232 devices. Conversely, when RS232 voltage signal levels are sent from the RS232 device to the level translation IC, the level translation IC translates the RS232 voltage signal levels to the TTL voltage signal levels that can be recognized by the TTL device. A conventional level translation IC needs to connect to two power sources. One power source ranges from 0V to +5V in order to communicate with the TTL device, and the other power source ranges from 0V to +12V in order to communicate with the RS232 devices.

Although the level translation IC can implement bidirectional level translations between the TTL voltage signal levels and the RS232 voltage signal levels, the level translation IC has some disadvantages. The purchase costs of such a typical level translation IC is high. In addition, the level translation ICs must be connected to the power supplies of both the RS232 devices and the TTL devices in order to translate voltage signal levels.

Consequently, what is needed is desired an apparatus to enable an RS232 device to communicate with a TTL device without having a separate level translation IC.

### SUMMARY OF THE INVENTION

An objective of the present invention is to provide a circuit for translating voltage signal levels, and thereby enabling communication among devices utilizing different logic signal families, without having a separate level translation IC.

In order to fulfill the above-mentioned objective, a preferred embodiment of the present invention provides a circuit for translating RS232 voltage signal levels to TTL voltage signal levels. The circuit comprises: a first diode, the anode of the first diode being for receiving the RS232 voltage signal levels; a resistor, one end of the resistor being connected to the cathode of the first diode; and a zener diode, the cathode of the zener diode being connected to the other end of the resistor, and the anode of the zener diode being grounded.

The circuit of the present invention performs voltage signal level translation from the RS232 voltage signal levels to the TTL voltage signal levels by utilizing the zener breakdown effect of the zener diode. That is, by switching on and off the zener diode between the devices utilizing the different logic signal families. There is no need for a separate level translation IC.

Other objectives, advantages and novel features of the present invention will become more apparent from the following detailed description when taken in conjunction with the accompanying drawings, in which:

### BRIEF DESCRIPTION OF THE DRAWINGS

FIG. 1 is a diagram of an operating environment of a circuit for translating voltage signal levels according to a preferred embodiment of the present invention; and

FIG. 2 is a schematic diagram of input voltage signal levels and output voltage signal levels of the circuit of FIG. 1.

### DETAILED DESCRIPTION OF THE INVENTION

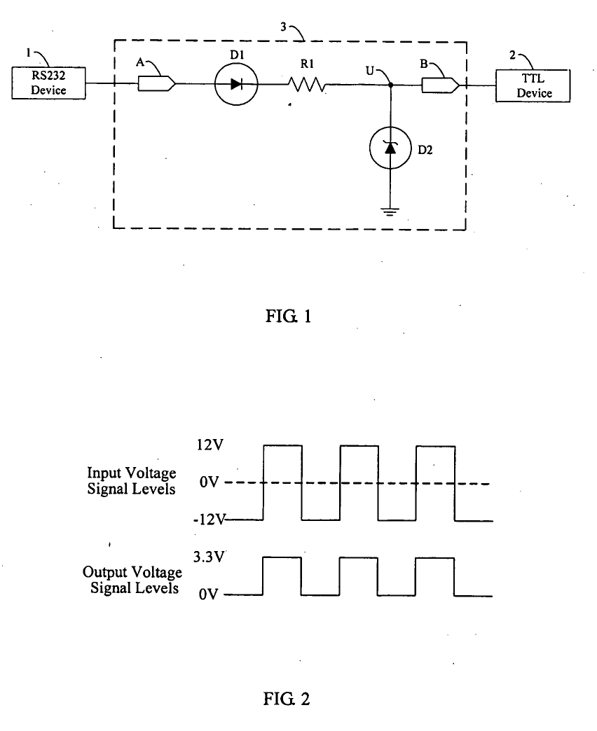

FIG. 1 is a diagram of an operating environment of a circuit 3 for translating voltage signal levels between an RS232 device 1 and a TTL device 2 according to a preferred embodiment of the present invention. In the exemplary embodiment of the present invention described herein, the RS232 device 1 supports the RS232 standard, which recognizes RS232 voltage signal levels that range from −12V to +12V. The TTL device 2 utilizes TTL voltage signal levels that range from 0V to +3.3V. The circuit 3 for translating the voltage signal levels is electronically connected to the RS232 device 1 and to the TTL device 2. If the RS232 device 1 outputs a −12V voltage signal level to the circuit 3, the circuit 3 translates the −12V voltage signal level to a 0V voltage signal level that is then transmitted to the TTL device 2. If the RS232 device 1 outputs a +12V voltage signal level to the circuit 3, the circuit 3 translates the +12V voltage signal level to a +3.3V voltage signal level that is then transmitted to the TTL device 2. Thus, the RS232 device 1 communicates with the TTL device 2 through the circuit 3.

The circuit 3 comprises an input end A, a diode D1 as a first switch, a resistor R1, a zener diode D2 as a second switch or a voltage-control electronic component, a node U, and an output end B. The circuit 3 translates the voltage signal levels by switching the zener diode D2 on and off. The anode of diode D1 is electronically connected to the RS232 device 1 through the input end A. One end of the resistor R1 is electronically connected to the cathode of diode D1, and the other end of the resistor R1 is electronically connected to the cathode of the zener diode D2 through the node U. The anode of the zener diode D2 is grounded. One end of the output end B is electronically connected to the node U, and other end of the output end B is electronically connected to the TTL device 2. In the preferred embodiment, the resistor R1 is used for limiting the current crossing the diode D1 in order to avoid burning out the diode D1, and a voltage loaded on the resistor R1 can be ignored. In the preferred embodiment, the diode D1 is a 1N4148 type, which can bear a maximum input reverse voltage of −12V. The zener diode D2 is an MMSZ5226B type, which can bear a maximum input positive voltage across the diode D1. A zener voltage signal level of the zener diode D2 is +3.3V.

FIG. 2 is a schematic diagram of input voltage signal levels and output voltage signal levels of the circuit 3. In the illustrated embodiment, V_{U} represents a voltage between the node U and ground, and V_{D2} represents a zener voltage of the zener diode D2. The circuit 3 completes voltage signal levels translation by utilizing the zener breakdown effect of the zener diode D2. When the zener diode D2 operates in a positive voltage, the zener diode D2 works the same way as a general diode does. The zener diode D2 does not turn on until the V_{U} is higher than the zener voltage V_{D2}. When the zener diode D2 operates in a reverse voltage, and the reverse voltage is higher than the zener voltage of the zener diode D2, the zener diode D2 generates zener breakdown effect. Thus, the V_{U} is approximately equal to the V_{D2}.

When the input end A receives the −12V voltage signal level from the RS232 device 1, the diode D1 is turned off. Thus, the V_{U} is 0V voltage signal level, which is lower than the V_{D2}. In such case, the zener diode D2 is turned off, and the voltage signal level of the output end B is a 0V. In this way, the circuit 3 accomplishes the voltage signal levels translation from the −12V RS232 voltage signal level to the 0V TTL voltage signal level.

In contrast, when the input end A receives the +12V voltage signal level from the RS232 device 1, the diode D1 is turned on. The value of the resistor R1 can be ignored. The V_{U} is a +12V voltage signal level, which is larger than the V_{D2}. In such case, the zener diode D2 breaks down based on the zener breakdown effect, and the V_{U} is equal to the V_{D2}. The voltage of the output end B is equal to the V_{D2}; that is, the +3.3V voltage signal level. In this way, the circuit 3 accomplishes the voltage signal level translation from the +12V RS232 voltage signal level to the +3.3V TTL voltage signal level.

While a particular embodiment of the present invention has been described above, it should be understood that it has been presented by way of example only and not by way of limitation. Thus the breadth and scope of the present invention should not be limited by the above-described exemplary embodiment, but should be defined only in accordance with the following claims and their equivalents.

What is claimed is:

1. A circuit for translating first voltage signals to second voltage signals, comprising:
a first diode, the anode of the first diode being for receiving the first voltage signal;
a resistor, one end of the resistor being connected to the cathode of the first diode;
and a zener diode, the cathode of the zener diode being connected to the other end of the resistor, and the anode of the zener diode being grounded.

2. The circuit as recited in claim 1, further comprising an input end being connected to the anode of the diode for receiving the first voltage signal.

3. The circuit as recited in claim 1, further comprising an output end being connected to the cathode of the zener diode for outputting the second voltage signal.

4. The circuit as recited in claim 1, wherein the first voltage signal is an RS232 (recommended standard 232) voltage signal.

5. The circuit as recited in claim 1, wherein the second voltage signal is a Transistor-Transistor-Logic (TTL) voltage signal.

6. A circuit for translating first signals with a first preset voltage level to second signals with a second preset voltage level, comprising:
an input end for receiving said first signals;
an output end for transmit said second signals out of said circuit;
a first switch connected to said input end;
and a voltage-control second switch connected between said first switch and said output end at one end thereof, and another end of said second switch being grounded;
wherein portions of said first signals are capable of turning on said first switch and then triggering voltage-control function of said second switch so as to generate said second signals with second voltage levels for transmission of said output end, and other portions of said first signals are capable of turning off said first switch and subsequently said second switch.

7. The circuit as recited in claim 6, wherein said second switch is a Zener diode with a Zener voltage level as said second voltage level for said voltage-control function.

8. The circuit as recited in claim 6, wherein said first switch is a diode capable of being switched based on said first voltage level of said first signals.

9. A method for translating first signals with a first preset voltage level to second signals with a second preset voltage level, comprising:
providing a first device for transmitting said first signals;
providing a second device for receiving said second signals;
connecting a switch between said first and second devices;
connecting a voltage-control electronic component between said switch and said second device;
transmitting said second signals to said second device based on voltage control of said electronic component.

10. The method as recited in claim 9, wherein said first device is a recommended standard 232 (RS232) compatible device.

11. The method as recited in claim 9, wherein said second device is a Transistor-Transistor-Logic (TTL) compatible device.

12. The method as recited in claim 9, wherein said switch is a diode capable of being switched based on said first voltage level of said first signals.

13. The method as recited in claim 9, wherein said voltage-control electronic component is a Zener diode having a Zener voltage level as said second voltage level.
